(19) United States
(12) Patent Application Publication
(10) Pub. No.: US 2018/0053806 A1
(43) Pub. Date: Feb. 22, 2018

(54) SENSING DEVICE

(71) Applicant: PRIMAX ELECTRONICS LTD., Taipei (TW)

(72) Inventor: Tsung-Hui Chao, Taipei (TW)

(21) Appl. No.: 15/337,690

(22) Filed: Oct. 28, 2016

(30) Foreign Application Priority Data
Aug. 19, 2016 (TW) 105126580

(51) Int. Cl. H01L 27/146; G06K 9/00

(52) U.S. Cl. CPC H01L 27/14678; G06K 9/0004

(57) ABSTRACT

The present invention relates to a sensing device, including a protective cover to be in contact with an object, a receiving electrode module, and a substrate. The receiving electrode module includes an insulating plate, a receiving electrode layer, and a conductive circuit layer. The insulating plate can separate the receiving electrode module from the substrate. The receiving electrode layer is disposed on the insulating plate. The conductive circuit layer covers the receiving electrode layer and is separately electrically connected to the receiving electrode layer and the substrate. The sensing device in the present invention, the conductive circuit layer takes place of a conductor wire and a guard layer in a conventional sensing device, so that sensitivity of the sensing device can be improved.

### FIELD OF THE INVENTION

The present invention relates to a sensing device, and in particular, to a sensing device capable of sensing a fingerprint of a user.

### BACKGROUND OF THE INVENTION

In recent years, a fingerprint identification technology is applied to various electronic products, so that a user can input a fingerprint to an electronic product, the electronic product stores the fingerprint, and the user can input the fingerprint of the user by using a fingerprint identification module, to unlock an electronic product. Unlocking an electronic product by using a fingerprint identification technology is faster and more convenient than a previous unlocking manner in which a password is manually entered, and therefore, the former unlocking manner is preferred by users. Moreover, there is also an increasing requirement on sensing devices having a fingerprint identification function.

Referring to FIG. 1, FIG. 1 is a schematic structural diagram of a conventional sensing device. A conventional sensing device 1 includes a protective cover 10, a transmitting electrode module 11, a receiving electrode module 12, and a substrate 13. The receiving electrode module 12 includes a guard layer 121, a receiving electrode layer 122, an insulating plate 123, and a conductor wire 124. These components are sequentially the protective cover 10, the guard layer 121, the receiving electrode layer 122, the insulating plate 123, the substrate 13, and the transmitting electrode module 11 from top to bottom. The conductor wire 124 is located on sides of the receiving electrode layer 122 and the insulating plate 123. The protective cover 10 is disposed on the receiving electrode module 12 and exposes outside as a part of the sensing device 1. The protective cover 10 can protect the receiving electrode module 12 from being damaged and be provided for touching of a finger of a user. The transmitting electrode module 11 is disposed on a lower surface of the substrate 13, and is configured to generate a detection signal, so as to detect a surface of a finger touching the protective cover 10. The detection signal is reflected by the surface of the finger on the protective cover 10 and converted into a reflection signal.

The receiving electrode module 12 is disposed between the protective cover 10 and the substrate 13, and is configured to receive the reflection signal. In the receiving electrode module 12, the insulating plate 123 is disposed on an upper surface of the substrate 13, and can separate the receiving electrode layer 122 from the substrate 13. The receiving electrode layer 122 is disposed on an upper surface of the insulating plate 123 and can receive the reflection signal. The conductor wire 124 is separately electrically connected to the receiving electrode layer 122 and the substrate 13. The guard layer 121 covers the receiving electrode layer 122, to protect the receiving electrode layer 122 from being damaged by an external force. The insulating plate 123 is made of a polyvinylidene fluoride (Polyvinylidene fluoride, PVDF) material. The guard layer 121 is made of an acryl material. The receiving electrode layer 122 is made of a metal conductive material or an indium tin oxide (Indium Tin Oxide, ITO). The metal conductive material includes an aluminum material, an aluminum alloy material, a bronze material, a bronze alloy material, a nickel material, a gold material, a platinum material, and the like. The substrate 13 is disposed between the receiving electrode module 12 and the transmitting electrode module 11, and can obtain a surface imaging of a finger according to a reflection signal. The substrate 13 is thin-film transistor (Thin-Film Transistor, TFT) glass.

An operation principle of the structure of the foregoing conventional sensing device 1 is: When a user puts a finger on the protective cover 10, the transmitting electrode module 11 generates a detection signal, and the detection signal is transmitted to the protective cover 10 in an ultrasonic form, to detect a surface of the finger touching the protective cover 10. The detection signal is reflected by the surface of the finger on the protective cover 10, and in this case, the detection signal is defined as a reflection signal. The reflection signal is transmitted to the receiving electrode layer 122 in an ultrasonic form, so that the receiving electrode layer 122 transmits the reflection signal to the substrate 13 by using the conductor wire 124. Actually, the substrate 13 connects to a processor (which is not shown in the figure). When the substrate 13 receives the reflection signal, the processor can calculate the current strength of the surface of the finger according to the reflection signal, so as to obtain a surface imaging of the finger through calculation.

However, although the guard layer 121 can protect the receiving electrode layer 122, the guard layer 121 lowers sensitivity of receiving a reflection signal by the receiving electrode layer 122, thereby easily causing an error in fingerprint identification.

### SUMMARY OF THE INVENTION

An objective of the present invention is to provide a sensing device whose sensitivity can be improved.

In a preferred embodiment, the present invention provides a sensing device, configured to retrieve a surface imaging of an object and including: a protective cover, a transmitting electrode module, a receiving electrode module, and a substrate. The protective cover is configured to be in contact with the object; the transmitting electrode module is configured to output a detection signal to the protective cover, to detect a surface of the object; The receiving electrode module is disposed under the protective cover and configured to receive a reflection signal reflected by the surface of the object; and The substrate is disposed under the receiving electrode module and configured to obtain the surface imaging of the object according to the reflection signal, where the receiving electrode module includes an insulating plate, a receiving electrode layer, and a conductive circuit layer. The insulating plate is disposed at the bottom of the receiving electrode module and configured to separate the receiving electrode module from the substrate or the transmitting electrode module; the receiving electrode layer is disposed on the insulating plate and configured to receive the reflection signal; and the conductive circuit layer covers the receiving electrode layer and separately electrically connects to the receiving electrode layer and the substrate, to establish an electrical connection between the receiving electrode layer and the substrate.

In a preferred embodiment, the present invention provides a sensing device, configured to retrieve a surface imaging of an object and including: a protective cover, a transmitting electrode module, a receiving electrode module, and a substrate. The protective cover is configured to be in contact with the object; the transmitting electrode module is configured to output a detection signal to the protective cover, to detect a surface of the object; the receiving electrode module is disposed under the protective cover and configured to receive a reflection signal reflected by the surface of the object; and the substrate is disposed under the receiving electrode module and configured to obtain the surface imaging of the object according to the reflection signal, where the receiving electrode module includes: an insulating plate and a conductive circuit layer. The insulating plate is disposed at the bottom of the receiving electrode module and configured to separate the receiving electrode module from the substrate or the transmitting electrode module; and the conductive circuit layer covers the insulating plate and electrically connects to the substrate, to receive the reflection signal and transmit the reflection signal to the substrate.

In short, in the sensing device in the present invention, a conductive circuit layer printed in a stepped shape takes place of a conductor wire and a guard layer in the conventional sensing device, so that the sensing device can be not provided with a guard layer with which sensitivity is lowered. In other words, sensitivity of the sensing device in the present invention can be improved. In addition, a preferred operation can be used: the conductive circuit layer printed in a stepped shape may be used to take place of a conductor wire, a guard layer, and a receiving electrode layer in a conventional sensing device, which not only can improve sensitivity, but also can reduce thickness of a sensing device.

### BRIEF DESCRIPTION OF THE DRAWINGS

FIG. 1 is a schematic structural diagram of a conventional sensing device;

FIG. 2 is a schematic structural diagram of a sensing device of the present invention in a first preferred embodiment; and

FIG. 3 is a schematic structural diagram of a sensing device of the present invention in a second preferred embodiment.

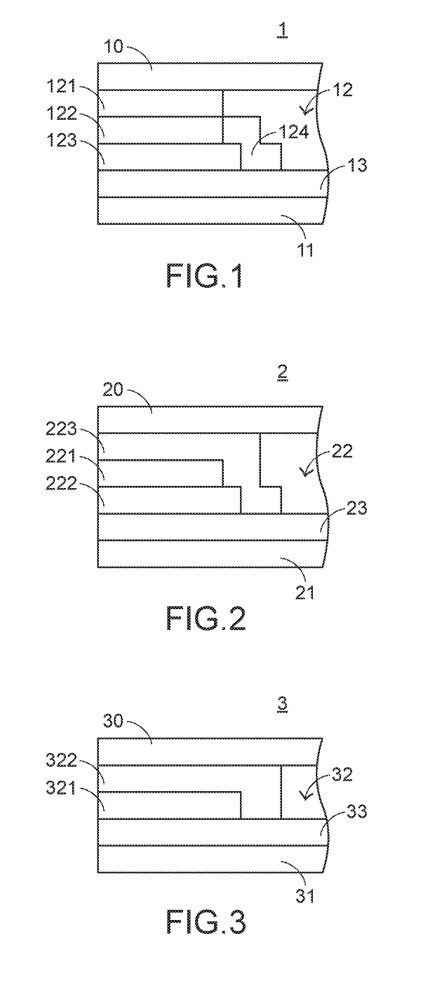

### DETAILED DESCRIPTION OF THE PREFERRED EMBODIMENT

The present invention provides a sensing device, to solve a conventional technical problem. Referring to FIG. 2, FIG. 2 is a schematic structural diagram of a sensing device of the present invention in a first preferred embodiment. The sensing device 2 can retrieve a surface imaging of an object (which is not shown in the figure), and includes a protective cover 20, a transmitting electrode module 21, a receiving electrode module 22, and a substrate 23. The receiving electrode module 22 includes a receiving electrode layer 221, an insulating plate 222, and a conductive circuit layer 223. These components are sequentially the protective cover 20, the conductive circuit layer 223, the receiving electrode layer 221, the insulating plate 222, the substrate 23, and the transmitting electrode module 21 from top to bottom. The conductive circuit layer 223 covers the receiving electrode layer 221, the insulating plate 222, and a part of the substrate 23. In the preferred embodiment, the object is a finger of a user.

The protective cover 20 is located at the top of the sensing device 2, and exposes outside as a part of the sensing device 2, and therefore can be in contact with an object. The transmitting electrode module 21 is disposed on a lower surface of the substrate 23 and is electrically connected to the substrate 23, and configured to generate a detection signal, so as to detect a surface of an object touching the protective cover 20. The detection signal is reflected by the surface of the object on the protective cover 20. The reflected detection signal is defined as a reflection signal. The receiving electrode module 22 is disposed under the protective cover 20 and on the substrate 23, and is configured to receive the reflection signal reflected by the surface of the object. The substrate 23 is disposed under the receiving electrode module 22 and on the transmitting electrode module 21, and configured to obtain a surface imaging of the object according to the reflection signal. In the preferred embodiment, the substrate 23 is thin-film transistor (TFT) glass.

In the receiving electrode module 22, the insulating plate 222 is disposed on an upper surface of the substrate 23, and can separate the receiving electrode layer 221 from the substrate 23. The receiving electrode layer 221 is disposed on an upper surface of the insulating plate 222, and can receive the reflection signal. The conductive circuit layer 223 covers the receiving electrode layer 221 and a part of the substrate 23, and is separately electrically connected to the receiving electrode layer 221 and the substrate 23. The conductive circuit layer 223 has two functions: First, establishing an electrical connection between the receiving electrode layer 221 and the substrate 23; second, protecting the receiving electrode layer 221 from being damaged by an external force. In the preferred embodiment, the receiving electrode layer 221 is made of a metal conductive material or an indium tin oxide (ITO). The conductive circuit layer 223 is formed of a silver material printed on an upper surface of the receiving electrode layer 221 and the upper surface of the substrate 23, so that the conductive circuit layer 223 covers the receiving electrode layer 221, the insulating plate 222, and a part of the substrate 23. The conductive circuit layer 223 is presented in a stepped form. The insulating plate 222 is made of a polyvinylidene fluoride (PVDF) material.

An operation principle of detecting by the sensing device 2 the surface of the object on the protective cover 20 is the same as a conventional technical principle, and details are not described herein again. Through operation of the sensing device 2, the surface imaging of the object can be obtained. There are two points needing to be noted that: First, in the sensing device 2 in the present invention, the conductive circuit layer 223 printed in a layer shape takes place of a conventional conductor wire and a guard layer; because the sensing device 2 is not provided with a guard layer, sensitivity of receiving the reflection signal by the receiving electrode layer 221 is not affected. In other words, sensitivity of the sensing device in the present invention can be improved. Second, in the preferred embodiment, the transmitting electrode module 21 is disposed on the lower surface of the substrate 23, which is merely used as an example, but not a limitation. In another preferred embodiment, the transmitting electrode module may also be disposed on an upper surface of the substrate, that is, the transmitting electrode module is disposed between the receiving electrode layer and the substrate. In this case, the insulating plate separates the receiving electrode module from the transmitting electrode module.

In addition, the present invention further provides a second preferred embodiment different from the foregoing operations. Referring to FIG. 3, FIG. 3 is a schematic structural diagram of a sensing device of the present invention in a second preferred embodiment. The sensing device 3 includes a protective cover 30, a transmitting electrode module 31, a receiving electrode module 32, and a substrate 33. The receiving electrode module 32 includes an insulating plate 321 and a conductive circuit layer 322. These components are sequentially the protective cover 30, the conductive circuit layer 322, the insulating plate 321, the substrate 33, and the transmitting electrode module 31 from top to bottom. The conductive circuit layer 322 covers the insulating plate 321 and a part of the substrate 33. A difference between the sensing device 3 in the preferred embodiment and the first preferred embodiment lies in that, the receiving electrode layer 223 in the first preferred embodiment is removed, and the conductive circuit layer 322 takes place of the receiving electrode layer 223.

It can be known from FIG. 3 that, the insulating plate 321 is disposed at the bottom of the receiving electrode module 32, and can separate the receiving electrode module 32 from the substrate 33. The conductive circuit layer 322 is made of a silver material printed on an upper surface of the insulating plate 321 and a part of an upper surface of the substrate 33, so that the conductive circuit layer 322 covers the insulating plate 321 and the part of substrate 33 and can be electrically connected to the substrate 33. Compared with the first preferred embodiment, in the preferred embodiment, the conductive circuit layer 322 takes place of the receiving electrode layer 223. Therefore, the receiving electrode module 32 in the preferred embodiment can have relatively small thickness and can be lighter.

It can be known from the above that, in the sensing device in the present invention, a conductive circuit layer printed in a layer shape takes place of a conductor wire and a guard layer in the conventional sensing device, so that the sensing device can be not provided with a guard layer with which sensitivity is lowered. In other words, sensitivity of the sensing device in the present invention can be improved. In a preferred operation, the conductive circuit layer printed in a stepped shape may be used to take place of a conductor wire, a guard layer, and a receiving electrode layer in a conventional sensing device, which not only can improve sensitivity, but also can reduce thickness of a sensing device.

The above descriptions are merely preferred embodiments of the present invention, and are not intended to limit the patent application scope of the present invention, and therefore, any equivalent change or modification made without departing from the spirits of the invention falls within the patent application scope of this specification.

What is claimed is:

1. A sensing device, configured to retrieve a surface imaging of an object and comprising:
a protective cover, configured to be in contact with the object;
a transmitting electrode module, configured to output a detection signal to the protective cover, to detect a surface of the object;
a receiving electrode module, disposed under the protective cover and configured to receive a reflection signal reflected by the surface of the object; and
a substrate, disposed under the receiving electrode module and configured to obtain the surface imaging of the object according to the reflection signal, wherein the receiving electrode module comprises:
an insulating plate, disposed at the bottom of the receiving electrode module and configured to separate the receiving electrode module from the substrate or the transmitting electrode module;
a receiving electrode layer, disposed on the insulating plate and configured to receive the reflection signal; and
a conductive circuit layer, covering the receiving electrode layer and separately electrically connecting to the receiving electrode layer and the substrate, to establish an electrical connection between the receiving electrode layer and the substrate.

2. The sensing device according to claim 1, wherein the transmitting electrode module is disposed between the insulating plate and the substrate and is electrically connected to the substrate; and the insulating plate separates the transmitting electrode module from the receiving electrode layer.

3. The sensing device according to claim 1, wherein the transmitting electrode module is disposed under the substrate and is electrically connected to the substrate; and the insulating plate separates the substrate from the receiving electrode layer.

4. The sensing device according to claim 1, wherein the receiving electrode layer is made of a metal conductive material or an indium tin oxide (ITO), and the conductive circuit layer is formed of a silver material printed on an upper surface of the receiving electrode layer and an upper surface of the substrate, so that the conductive circuit layer covers the receiving electrode layer, the insulating plate, and a part of the substrate.

5. The sensing device according to claim 1, wherein the insulating plate is made of a polyvinylidene fluoride (PVDF) material, and the substrate is thin-film transistor (TFT) glass.

6. A sensing device, configured to retrieve a surface imaging of an object and comprising:
a protective cover, configured to be in contact with the object;
a transmitting electrode module, configured to output a detection signal to the protective cover, to detect a surface of the object;
a receiving electrode module, disposed under the protective cover and configured to receive a reflection signal reflected by the surface of the object; and
a substrate, disposed under the receiving electrode module and configured to obtain the surface imaging of the object according to the reflection signal, wherein the receiving electrode module comprises:
an insulating plate, disposed at the bottom of the receiving electrode module and configured to separate the receiving electrode module from the substrate or the transmitting electrode module; and
a conductive circuit layer, covering the insulating plate and electrically connecting to the substrate, to receive the reflection signal and transmit the reflection signal to the substrate.

7. The sensing device according to claim 6, wherein the transmitting electrode module is disposed between the insulating plate and the substrate and is electrically connected to the substrate.

8. The sensing device according to claim 6, wherein the transmitting electrode module is disposed under the substrate and is electrically connected to the substrate.

9. The sensing device according to claim 6, wherein the conductive circuit layer is made of a silver material printed on an upper surface of the insulating plate and an upper surface of the substrate, so that the conductive circuit layer covers the insulating plate and a part of the substrate.

10. The sensing device according to claim 6, wherein the insulating plate is made of a polyvinylidene fluoride material, and the substrate is thin-film transistor glass.
